(19) United States
(12) Patent Application Publication
(10) Pub. No.: US 2020/0388604 A1
(43) Pub. Date: Dec. 10, 2020

(54) MULTI-DIE INTERCONNECT

(71) Applicant: QUALCOMM Incorporated, San Diego, CA (US)

(72) Inventors: Byoungyong LEE, San Diego, CA (US); Changhan Hobie YUN, San Diego, CA (US)

(21) Appl. No.: 16/433,957

(22) Filed: Jun. 6, 2019

(51) Int. Cl. H01L 25/18; H01L 23/528; H01L 23/00; H01L 25/00; H01L 21/48

(52) U.S. Cl. CPC H01L 25/18; H01L 23/5283; H01L 24/32; H01L 25/50; H01L 2224/73253; H01L 24/94; H01L 24/73; H01L 2224/32137; H01L 21/4857

(57) ABSTRACT

A multiple die (multi-die) module includes at least first and second dies of different technologies assembled so that edges of the first and second dies are in contact with each other. The edges of the first and second dies include protrusions and recesses configured to be press fitted. Edge interconnects are formed on the protrusions and/or the recesses such that when the first and second dies are assembled, they are electrically connected to each other.

### TECHNICAL FIELD

The field of the disclosed subject matter relates to device modules. In particular, the field of the disclosed subject matter relates to device modules with multiple dies and to methods of interconnecting the multiple dies.

### BACKGROUND

FIG. 1A illustrates a top view and FIGS. 1B and 1C illustrate side views of a conventional multi-die module 100. The multi-die module 100 is an example of a multi-function module such as a power amplifier module integrated duplexer (PAMid). In the multi-die module 100, multiple dies 120, 130, 140 are assembled on a laminate 110. Passive components 160 (e.g., capacitors, inductors, resistors, etc.) are also assembled on the laminate 110. The dies 120, 130, 140 are interconnected to each other through interconnects 150 such as bondwires (for non-flip chip) as illustrated in FIG. 1B or pillars and redistribution layers (RDLs) (for flip chip) as illustrated in FIG. 1C.

One disadvantage of the conventional multi-die module 100 is an increase in the module size due to the keep-out-zone (KOZ) necessitated by interconnects 150 to achieve die-to-die connections. Also, for high frequency applications (e.g., greater than 25 GHz) such as in millimeter wave (mmW) applications for 5G, transmission loss of signals, e.g., through the interconnects 150, can be very significant. Further, repeatability of assembly of the dies 120, 130, 140 and interconnects 150 may not be satisfactory.

### SUMMARY

This summary identifies features of some example aspects, and is not an exclusive or exhaustive description of the disclosed subject matter. Whether features or aspects are included in, or omitted from this summary is not intended as indicative of relative importance of such features. Additional features and aspects are described, and will become apparent to persons skilled in the art upon reading the following detailed description and viewing the drawings that form a part thereof.

An exemplary multi-die module is disclosed. The module may comprise a first die and a second die. A first die edge of the first die may be in contact with a second die edge of the second die. The first die edge may comprise one or more protrusions and one or more recesses and the second die edge may comprise one or more protrusions and one or more recesses such that the protrusions of the first die edge are in contact with recesses of the second die edge and vice versa. Edge interconnects may be formed on sidewalls of at least one protrusion and/or at least one recess of the first die edge. Edge interconnects may also be formed on sidewalls of at least one protrusion and/or at least one recess of the second die edge. The edge interconnect of the at least one protrusion of the first die may be in contact with the edge interconnect of the at least one recess of the second die, and/or the edge interconnect of the at least one protrusion of the second die may be in contact with the edge interconnect of the at least one recess of the first die such that the first and second dies are electrically coupled to each other through the contacting edge interconnects.

An exemplary method of fabricating a multi-die module is disclosed. The method may comprise forming a first die, forming a second die, and assembling the first and second dies such that a first die edge of the first die is in contact with a second die edge of the second die. The first die edge may comprise one or more protrusions and one or more recesses and the second die edge may comprise one or more protrusions and one or more recesses such that the protrusions of the first die edge are in contact with recesses of the second die edge and vice versa. Edge interconnects may be formed on sidewalls of at least one protrusion and/or at least one recess of the first die edge. Edge interconnects may also be formed on sidewalls of at least one protrusion and/or at least one recess of the second die edge. The edge interconnect of the at least one protrusion of the first die may be in contact with the edge interconnect of the at least one recess of the second die, and/or the edge interconnect of the at least one protrusion of the second die may be in contact with the edge interconnect of the at least one recess of the first die such that the first and second dies are electrically coupled to each other through the contacting edge interconnects.

Another exemplary multi-die module is disclosed. The module may comprise a laminate and a plurality of dies on the laminate. The plurality of dies may comprise a first die and a second die. A first die edge of the first die may be in contact with a second die edge of the second die. The first die edge may comprise one or more protrusions and one or more recesses and the second die edge may comprise one or more protrusions and one or more recesses such that the protrusions of the first die edge are in contact with recesses of the second die edge and vice versa. Edge interconnects may be formed on sidewalls of at least one protrusion and/or at least one recess of the first die edge. Edge interconnects may also be formed on sidewalls of at least one protrusion and/or at least one recess of the second die edge. The edge interconnect of the at least one protrusion of the first die may be in contact with the edge interconnect of the at least one recess of the second die, and/or the edge interconnect of the at least one protrusion of the second die may be in contact with the edge interconnect of the at least one recess of the first die such that the first and second dies are electrically coupled to each other through the contacting edge interconnects.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of examples of one or more aspects of the disclosed subject matter and are provided solely for illustration of the examples and not limitation thereof.

FIGS. 1A, 1B, and 1C illustrate views of conventional device multi-die modules;

FIGS. 2A, 2B, and 2C illustrate views of exemplary multi-die modules according to one or more aspects;

FIGS. 3A and 3B illustrate 3D and 2D views of dies of a multi-die module and their edges according to one or more aspects;

FIGS. 4A, 4B, and 4C illustrate side views of exemplary multi-die modules including edge interconnects according to one or more aspects;

FIGS. 5A, 5B, and 5C illustrate other embodiments of multi-die modules according to one or more aspects;

FIGS. 6A and 6B illustrate exemplary arrangements of multi-die modules according to one or more aspects;

FIGS. 7A-1-7G illustrate examples of different stages of fabricating a multi-die module according to one or more aspects;

FIG. 8 illustrates a flow chart of an example method of fabricating a multi-die module according to one or more aspects; and

FIG. 9 illustrates examples of devices with a multi-die module integrated therein.

### DETAILED DESCRIPTION

Aspects of the subject matter are provided in the following description and related drawings directed to specific examples of the disclosed subject matter. Alternates may be devised without departing from the scope of the disclosed subject matter. Additionally, well-known elements will not be described in detail or will be omitted so as not to obscure the relevant details.

The word “exemplary” is used herein to mean “serving as an example, instance, or illustration.” Any aspect described herein as “exemplary” is not necessarily to be construed as preferred or advantageous over other aspects. Likewise, the term “aspects” does not require that all aspects include the discussed feature, advantage, or mode of operation.

The terminology used herein describes particular aspects only and should not be construed to limit any aspects disclosed herein. As used herein, the singular forms “a,” “an,” and “the” are intended to include the plural forms as well, unless the context clearly indicates otherwise. Those skilled in the art will further understand that the terms “comprises,” “comprising,” “includes,” and/or “including,” as used herein, specify the presence of stated features, integers, steps, operations, elements, and/or components, but do not preclude the presence or addition of one or more other features, integers, steps, operations, elements, components, and/or groups thereof.

Further, various aspects may be described in terms of sequences of actions to be performed by, for example, elements of a computing device. Those skilled in the art will recognize that various actions described herein can be performed by specific circuits (e.g., an application specific integrated circuit (ASIC)), by program instructions being executed by one or more processors, or by a combination of both. Additionally, these sequences of actions described herein can be considered to be embodied entirely within any form of non-transitory computer-readable medium having stored thereon a corresponding set of computer instructions that upon execution would cause an associated processor to perform the functionality described herein. Thus, the various aspects described herein may be embodied in a number of different forms, all of which have been contemplated to be within the scope of the claimed subject matter. In addition, for each of the aspects described herein, the corresponding form of any such aspects may be described herein as, for example, “logic configured to” and/or other structural components configured to perform the described action.

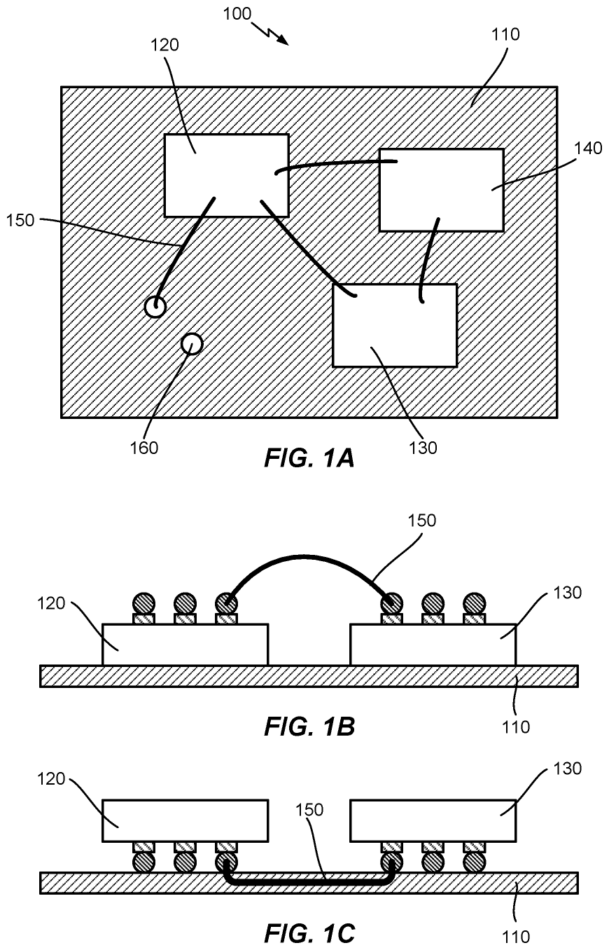

As indicated above, disadvantages of the conventional multi-die module 100 illustrated in FIGS. 1A, 1B, and 1C include, among others, increased module size, increased interconnection loss in high frequency applications, and assembly repeatability. In one or more aspect, it is proposed to address some or all issues associated with conventional multi-die module 100 through a multi-die interconnect technique that directly connects multiple dies instead of conventional interconnects such as bond wires. This can result in a reduced module size (high density), a reduced high frequency fringing effects, and increased assembly repeatability.

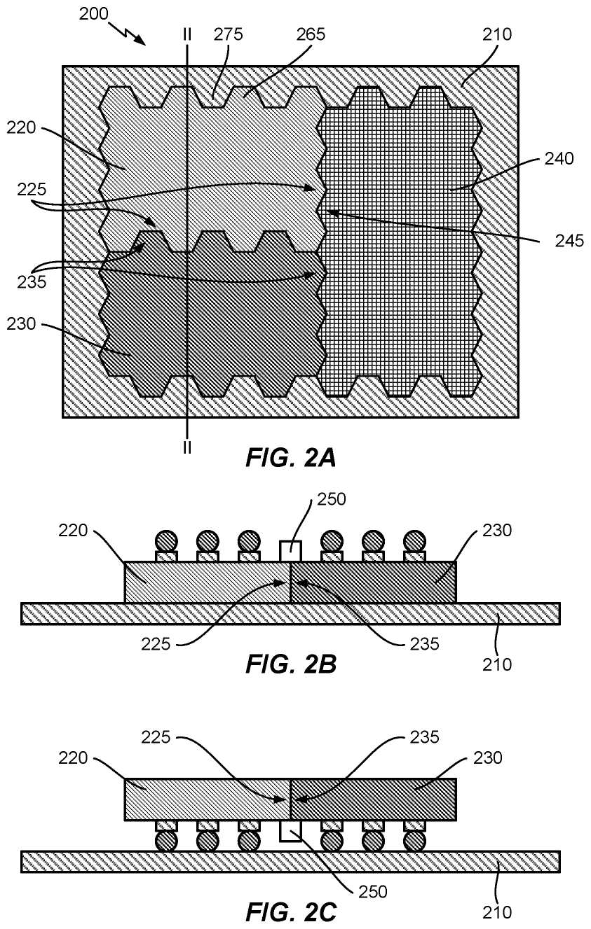

FIG. 2A illustrates a top view and FIGS. 2B and 2C illustrate side views of exemplary multi-die modules 200 according to one or more aspects. FIGS. 2B and 2C illustrate a cross-section along a line “II-II” in FIG. 2A. The multi-die module 200 may include a plurality of dies such as dies 220, 230, 240 on a laminate 210. While three dies are illustrated, the number of dies can be any number two or more. The multi-die module 200 of FIG. 2B is illustrated as being a non-flip chip orientation, while the multi-die module 200 of FIG. 2C is illustrated as being a flip chip orientation.

The dies 220, 230, 240 need not be of a same manufacturing technology. For example, the die 220 may be a silicon (Si) die, the die 230 may be a gallium arsenide (GaAs) die, and the die 240 may be a passive-on-glass (POG) die. Other technologies (not shown) may include generally group III-V dies (e.g., GaAs, aluminum nitride (AlN), indium phosphide (InP), etc.) and lumped passive components (e.g., resistor, capacitor, inductor, etc.). In general, at least two dies of the multi-die module 200 may be dies of different technologies. Note that even when two dies are both group III-V dies, they still may be different. For example, one may be a GaAs die and another may be an InP die. The proposed multi-die module 200 is particularly useful in interconnecting dies of different technologies.

The dies 220, 230, 240 may be in direct contact with each other. For the side views of FIGS. 2B and 2C, dies 220, 230—also referred to as first and second dies 220, 230 respectively—are shown to be in contact with each other. However, as seen in FIG. 2A, the die 240 (also referred to as third die 240) may be in contact with one or both of the first die 220 and/or the second die 230.

In particular, the edges of the dies 220, 230, 240 may be in contact with each other. As illustrated in FIG. 2A, the first die 220 may have multiple first die edges 225, the second die 230 may have multiple second die edges 235, and the third die 240 may have multiple third die edges 245. A die edge 225, 235, 245 may comprise one or more protrusions 265 (or convex portions) and one or more recesses 275 (or concave portions). The protrusions 265 and the recesses 275 may be shaped such that the protrusions 265 of one die such as the first die 220 are in contact with the recesses 275 of another die such as the second die 230, and vice versa as seen in FIGS. 2B and 2C.

For ease of description, the die edges 225, 235, 245 may be described as being a male edge, a female edge, or a mixed edge. In this context, a male edge is defined as an edge in which both ends of the edge are protrusions 265, a female edge is defined as an edge in which both ends of the edge are recesses 275, and a mixed edge is defined as an edge in which one end is a protrusion 265 and the other end is a recess 275. As defined, then it can be said that all first die edges 225 of the first die 220 are male, and all second die edges 235 of the second die 230 are female. It can also be said that the third die 240 has one third die edge 245 that is male (bottom edge), one third die edge 245 that is female (top edge), and two third die edges 245 that are mixed (side edges).

The dies 220, 230, 240 may include one or more edge interconnects 250 formed on protrusions 265 and/or the recesses 275 to enable electrical die-to-die electrical coupling. For example, the edge interconnects 250 of the protrusions 265 of the first die 220 may be in contact with the edge interconnects 250 of the recesses 275 of the second die 230. Alternatively or in addition thereto, the edge interconnects 250 of the protrusions 265 of the second die 230 may be in contact with the edge interconnects 250 of the recesses 275 of the first die 220. In this way, the first and second dies 220, 230 may be electrically coupled to or connected to each other through the contacting edge interconnects 250.

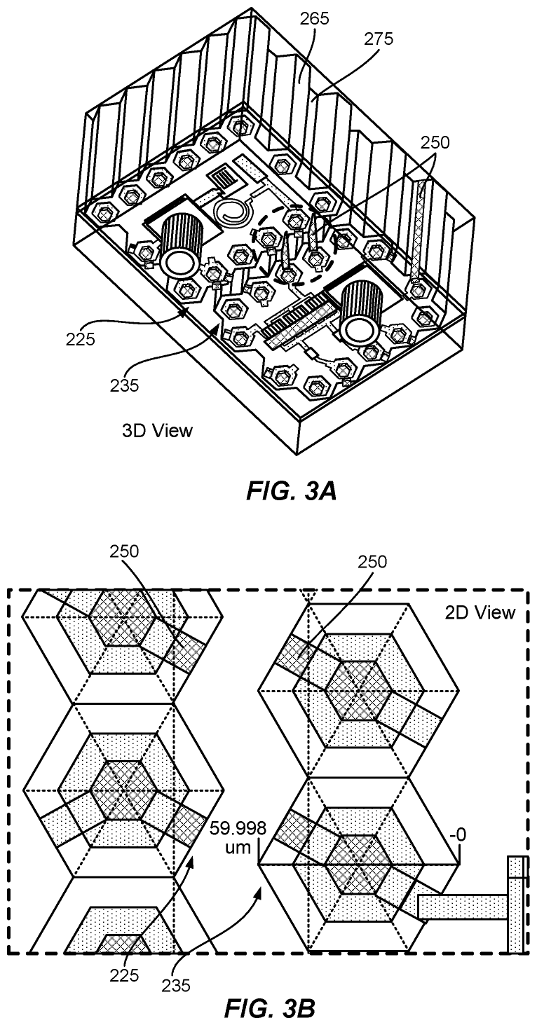

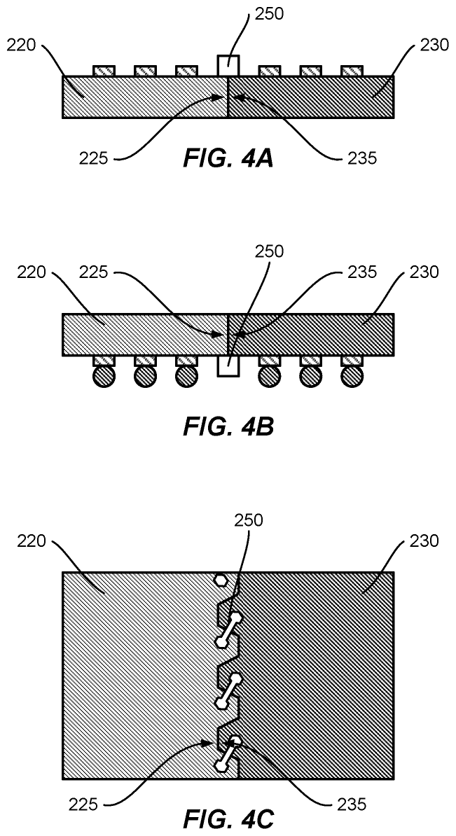

FIGS. 3A and 3B illustrate 3D and 2D views of dies of a multi-die module, which provide more details of the edge interconnects 250. As seen in FIG. 3A, the edge interconnects 250 may be formed on sidewalls of the protrusions 265 and/or the recesses 275 of the die edges (e.g., first die edge 225, second die edge 235, etc.). As seen in FIGS. 4A, 4B, and 4C, bringing into contact the first and second die edges 225, 235 can also bring into contact the edge interconnects 250 of the first and second dies 220, 230. In FIGS. 4A, 4B, and 4C, the laminate 210 is not illustrated for simplicity. FIG. 4B illustrates a top view of FIG. 4A in which the first and second dies 220, 230 are in a non-flip chip orientation. Alternatively, FIG. 4C illustrates a bottom view of FIG. 4B in which the first and second dies 220, 230 are in a flip chip orientation.

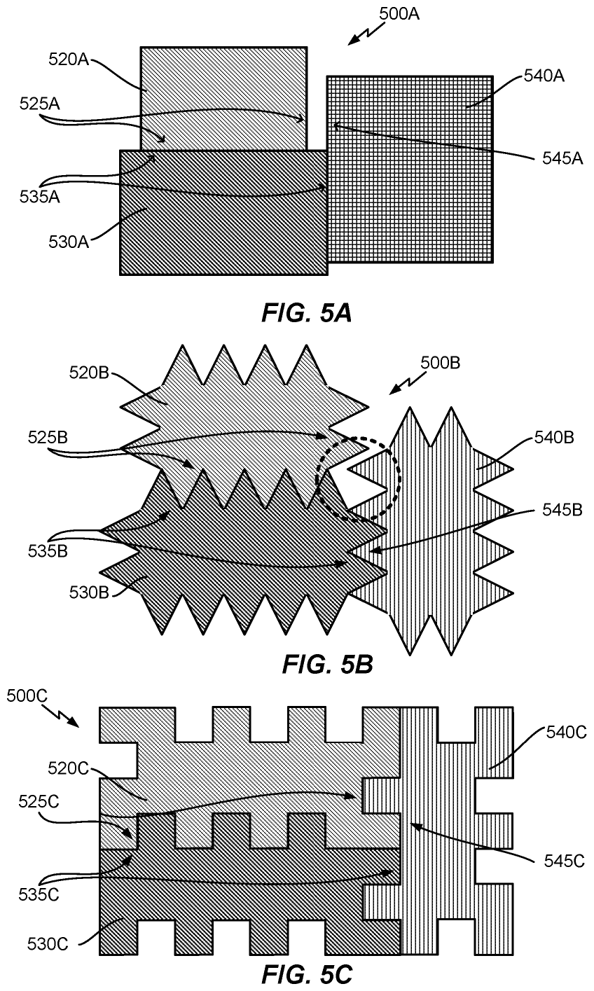

In FIG. 2A-4C, the protrusions 265 and the recesses 275 are illustrated as having hexagonal shapes. But as seen in FIGS. 5A, 5B, and 5C, other shapes are also contemplated. For example, FIG. 5B illustrates a multi-die module 500B with dies 520B, 530B, 540B whose respective edges 525B, 535B, 545B have protrusions and recesses that are triangular. As another example, FIG. 5C illustrates a multi-die module 500C with dies 520C, 530C, 540C whose respective edges 525C, 535C, 545C have protrusions and recesses that are rectangular. While not shown, it may be assumed that edge interconnects 250 are formed on the protrusions and recesses of the multi-die modules 500B, 500C. The male/female/mixed definitions of the edges may also apply to these example multi-die modules 500B, 500C.

The protrusions and recesses are not limited to hexagonal, triangular, and rectangular shapes. Indeed, it is contemplated that edges of some dies may not have any protrusions and recesses, i.e., the edges may be straight as seen in FIG. 5A which illustrates a multi-die module 500A with dies 520A, 530A, 540A. In this instance, it may be assumed that the edge interconnects are formed on the sidewall of the straight edge.

While the die edges may be shaped in a variety of ways, the hexagonal shapes offer some advantages over other shapes. The straight edge shapes of the dies in FIG. 5A make it relatively difficult to align the edge interconnects of different dies with each other. When the protrusions and recesses are triangular as seen in FIG. 5B, empty corners can result (see dashed circle). When the protrusions and recesses are rectangular as seen in FIG. 5C, it becomes relatively difficult to press fit the dies together due to sharp edges. Hexagonal shaped protrusions and recesses can deal with such drawbacks.

FIGS. 2A-5C illustrate that die edges of a die may have protrusions and recesses that are of the same shape. For example, FIG. 2A illustrates the first die edges 225 of the first die 220 as being hexagonal. As another example, FIG. 5B illustrates the die edges 525B of the die 520B as being triangular. Generally, in a multi-die module 200, one die of the module (e.g., the first die 220) may include a plurality of edges (e.g., plurality of first die edges 225) in which at least two edges of the die are shaped the same. Alternatively or in addition thereto, another die of the module (e.g., the first die 220) may include a plurality of edges (e.g., plurality of second die edges 235) in which at least two edges of the die are shaped the same.

However, while not shown in FIGS. 2A-5C, it is contemplated that a die may have die edges that are shaped differently. That is, in a multi-die module 200, one die of the module (e.g., the first die 220) may include a plurality of edges (e.g., plurality of first die edges 225) in which at least two edges of the die are shaped differently. For example, one edge of the die may be straight and another edge may include protrusions and recesses (e.g., hexagonal, triangular, rectangular, etc.) Alternatively or in addition thereto, another die of the module (e.g., the first die 220) may include a plurality of edges (e.g., plurality of second die edges 235) in which at least two edges of the die are shaped differently.

Of course, any combination of the above is also contemplated. That is, for a given die, all edges may be shaped the same. For another die, at least two edges may be shaped the same while at least two edges are shaped differently. Yet for another die, all edges may be shaped differently.

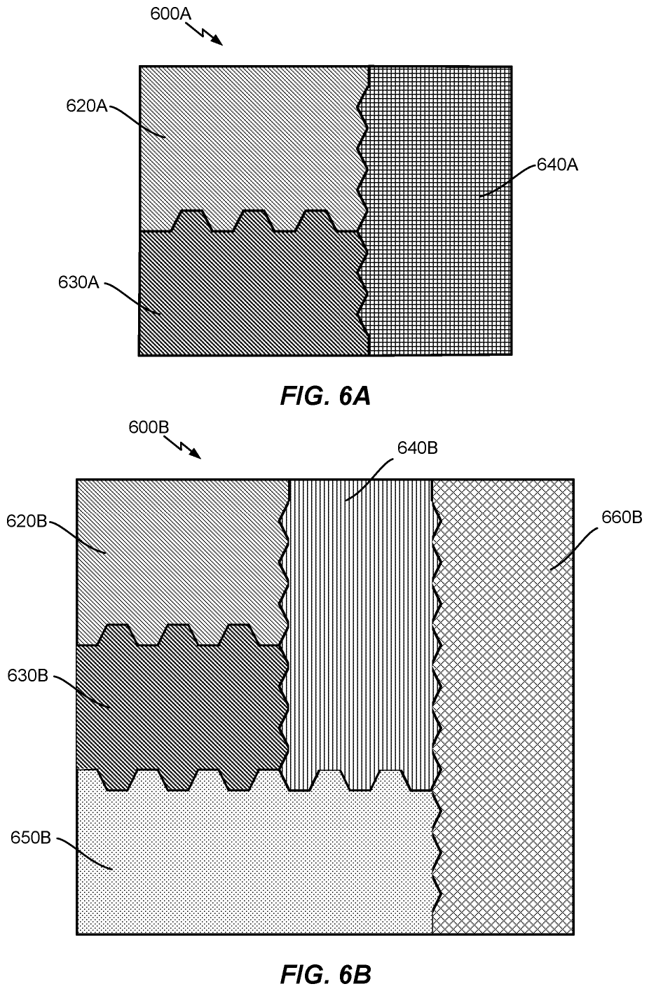

Due to the flexibility of shaping the edges, the dies of a multi-die module may be arranged in a variety of ways as illustrated in FIGS. 6A and 6B. FIG. 6A illustrates a multi-die module 600A that includes dies 620A, 630A, 640A with each die 620A, 630A, 640A having straight edges and edges with protrusions and recesses. FIG. 6B illustrates a multi-die module 600B that includes dies 620B, 630B, 640B, 650B, 660B also with each die 620B, 630B, 640B, 650B, 660B having straight edges and edges with protrusions and recesses. For simplicity, the protrusion and recesses of the dies in FIGS. 6A and 6B are illustrated as being hexagonal. But while not illustrated, it should be noted that the protrusion and recesses may be of any shape.

The proposed multi-die modules of FIGS. 2A-6B have several advantages over the conventional multi-die module of FIGS. 1A-1C. The following is a non-exhaustive list of some of the advantages:
Reduction in the keep-out-zone (KOZ)—e.g., at least 100 microns;
Increase in density (less real estate required since bondwires and pillars are not required);
Reduction of transmission wire losses, especially at mmW; and
Similar or lower assembly costs (assembly by press fit).

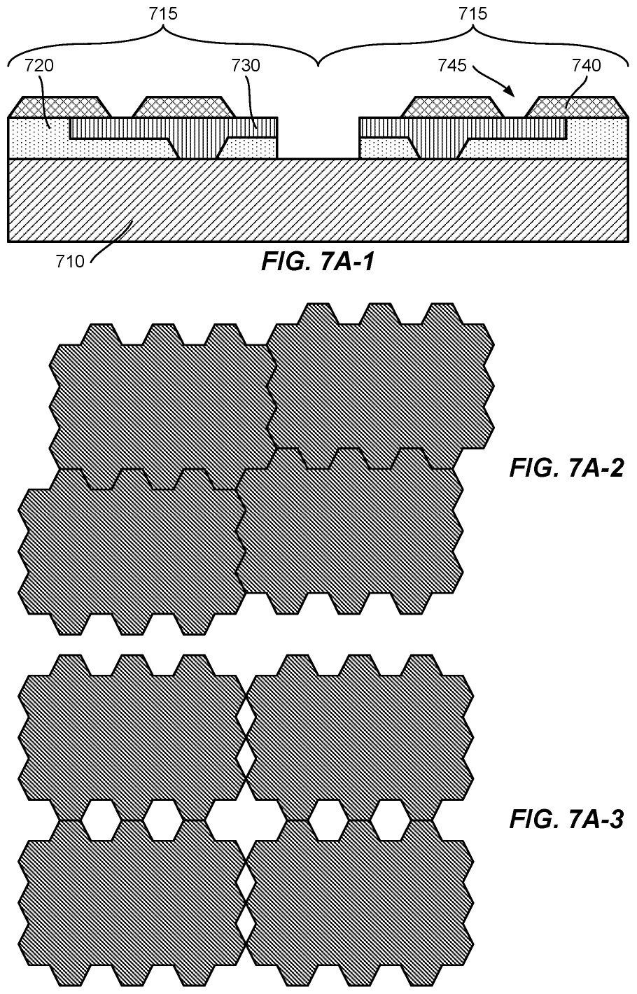

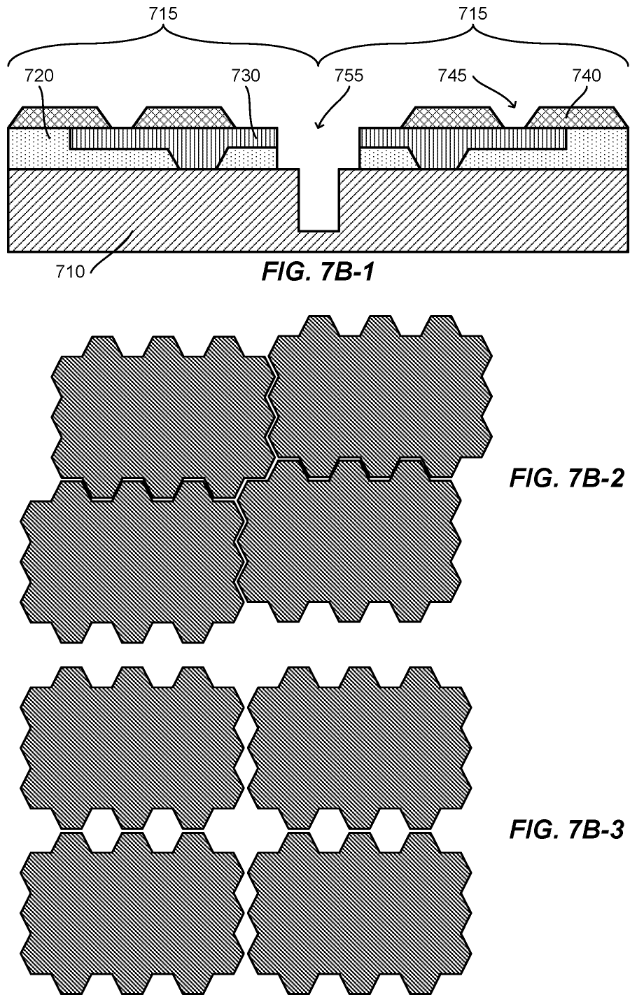

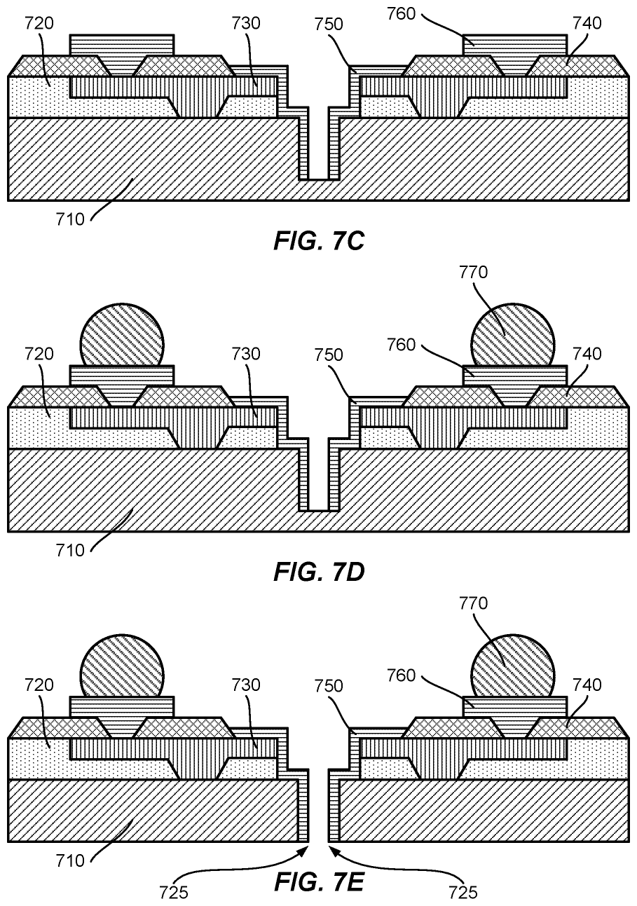

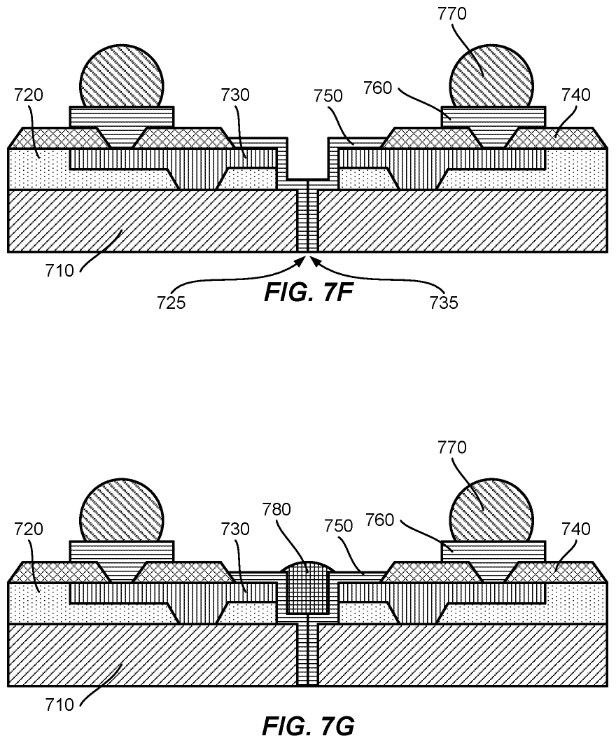

FIGS. 7A-1-7G illustrate examples of different stages of fabricating a multi-die module according to one or more aspects. The stages may be categorized into dice-before-grind (DBG) stages and assembly stages. The DBG stages (FIGS. 7A-1-7E) reflect processes to fabricate dies on one technology. In other words, the DBG stages would be performed for dies of each technology, e.g., for each of the dies 220, 230, 240, etc. The assembly stages (FIGS. 7F-7G) reflect processes to assemble different dies (of same or different technologies) together.

FIG. 7A-1 illustrates a side view of a stage in which a plurality of dies of a same technology may be fabricated on a wafer substrate 710. FIGS. 7A-2 and 7A-3 illustrate top views of the dies of the same stage. The plurality of dies may be fabricated on a corresponding plurality of die areas 715 of the wafer substrate 710. FIG. 7A-1 illustrates two of the dies on their corresponding die areas 715. FIGS. 7A-2 and 7A-3 illustrate different ways in which the plurality of die areas 715 (not numbered in FIGS. 7A-2, 7A-3), and hence the different ways in which the plurality of dies may be fabricated on the wafer substrate 710. For simplicity, hexagonal shapes are illustrated. But as indicated above, other shapes are contemplated.

As seen in FIG. 7A-1, each die may comprise a first passivation 720 on the wafer substrate 710. A final metal 730 may be formed on the wafer substrate 710 and on the first passivation 720. A final passivation 740 may be formed on the final metal 730 such that at least a portion of the final metal 730 is exposed through a final via 745 of the final passivation 740.

FIG. 7B-1 illustrates a side view of a stage in which a trench 755 may be formed in the wafer substrate 710 in between adjacent dies. FIGS. 7B-2 and 7B-3 illustrate top views of the dies of the same stage. The trench 755 may be formed by deep reactive ion etching (DRIE). Alternatively or in addition thereto, the trench 755 may be formed by a laser. The trench 755 may correspond to the edges of the die, i.e., correspond to the protrusions and recesses of the dies. FIG. 7B-2 shows the plurality of die area 715 of FIG. 7A-2 after forming the trench 755. Likewise, FIG. 7B-3 shows the plurality of die area 715 of FIG. 7A-3 after forming the trench 755.

FIG. 7C illustrates a stage in which metallizations 750 may be formed by metallizing the sidewalls of the trench 755, i.e., by metallizing the sidewalls corresponding to the protrusions 265 and the recesses 275 of the dies. The formed metallizations 750 provide die-to-die connections as edge interconnects 250. Metallizations 750 may also be formed on portions of the final passivation 740, the final metal 730, and the first passivation 720.

In an aspect, the metallizing may comprise forming an adhesion layer (e.g., Cr/Ti/TiW) and forming a seed layer (e.g., Cu/Ni) on the adhesion layer. The adhesion layer may be formed by sputtering. The seed layer may also be formed by sputtering, at least initially. The seed layer may be additionally formed by plating.

Note that the metallization process used to form the edge interconnects 250 may also be used to form under bump metallizations (UBM) 760 on the final passivation 740. For example, a single mask may be used to form the edge interconnects 250 and the UBM 760 simultaneously.

FIG. 7D illustrates a stage in which conductive bumps 770 (e.g., solder bumps) may be formed on the UBM 760. FIG. 7E illustrates a stage in which the plurality of dies are singulated into a plurality of individual dies. For example, the bottom of the wafer substrate 710 may be subjected to a grinding process such that the adjacent dies are no longer physically connected to each other.

As indicated above, FIGS. 7F-7G illustrate assembly stages in which individualized dies are assembled together as a multi-die module. In these figures, the left die may be a die of one wafer (e.g., a first die 220) and the right die may be a die of another wafer (e.g., a second die 230). FIG. 7F illustrates a stage in which the dies (e.g., first and second dies 220, 230) may be assembled to be in contact with other. For example, the dies may be press fitted together such that the edge interconnects (the metallizations 750) are in contact.

FIG. 7G illustrates an optional stage in which a joint paste 780 may be formed on the dies. The joint paste 780, e.g., a solder paste, may be formed so as to overlap the die edges (e.g., the first and second die edges 225, 235) to enhance securing the joint between the dies.

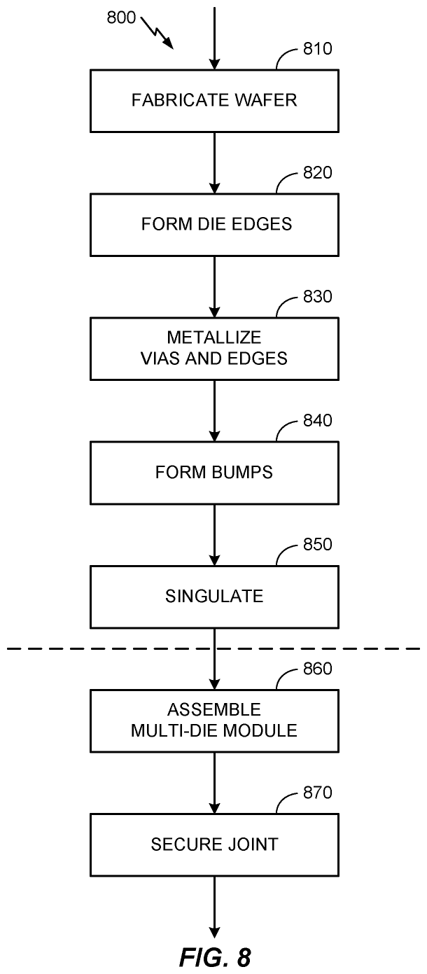

FIG. 8 illustrates a flow chart 800 of an example method of fabricating a multi-die module according to one or more aspects. Blocks 810-850 above the dashed line correspond to the DBG stages and blocks 860-870 correspond to the assembly stages. It should be noted that not all illustrated blocks of FIG. 8 need to be performed, i.e., some blocks may be optional. Also, the numerical references to the blocks of these figures should not be taken as requiring that the blocks should be performed in a certain order.

In block 810, a wafer of a plurality of dies of a same technology may be formed on a wafer substrate. Block 810 may correspond to the stage illustrated in FIGS. 7A-1, 7A-2, and 7A-3. In block 820, die edges may be formed in between adjacent dies. That is, a trench may be formed in between adjacent dies of the same technology. Block 820 may correspond to FIGS. 7B-1, 7B-2, and 7B-3.

In block 830, the die edges may be metallized. That is, the metallizations 750 may be formed on the sidewalls of the edges so as to form the edge interconnects 250. In an aspect, the same metallization process to form the edge interconnects 250 may also be simultaneously used to form the UBM 760. Block 830 may correspond to FIG. 7C.

In block 840, bumps 770 may be formed on the UBM 760. In block 850, the dies of the same technology may be singulated. Blocks 840 and 850 may respectively correspond to FIGS. 7D and 7E.

In block 860, individualized dies may be assembled together, e.g., on the laminate 210, such that the edge interconnects of the individual dies are in contact with other. Block 860 may correspond to FIG. 7F. In block 870, the dies may be further secured to each other by forming the joint paste 780. Block 870 may correspond to FIG. 7G.

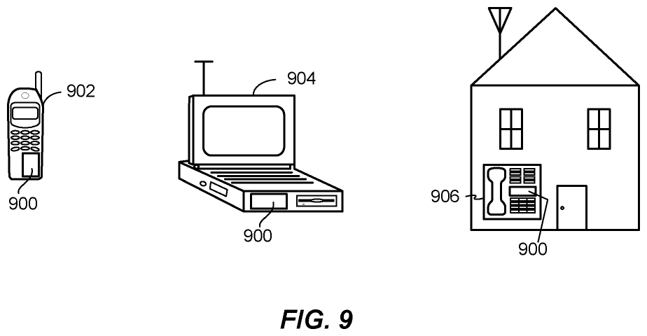

FIG. 9 illustrates various electronic devices that may be integrated with any of the aforementioned multi-die modules. For example, a mobile phone device 902, a laptop computer device 904, a terminal device 906 as well as wearable devices, portable systems, that require small form factor, extreme low profile, may include a device 900 that incorporates the multi-die modules as described herein. The device 900 may be, for example, any of the integrated circuits, dies, integrated devices, integrated device packages, integrated circuit devices, device packages, integrated circuit (IC) packages, package-on-package devices, system in package devices described herein. The devices 902, 904, 906 illustrated in FIG. 9 are merely exemplary. Other electronic devices may also feature the device 900 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), or any other device that stores or retrieves data or computer instructions, or any combination thereof.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general purpose processor, a DSP, an ASIC, an FPGA, or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more exemplary aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. A multi-die module, comprising:
a first die and a second die,
wherein a first die edge of the first die is in contact with a second die edge of the second die,
wherein the first die edge comprises one or more protrusions and one or more recesses and the second die edge comprises one or more protrusions and one or more recesses such that the protrusions of the first die edge are in contact with recesses of the second die edge and vice versa,
wherein edge interconnects are formed on:
sidewalls of at least one protrusion and/or at least one recess of the first die edge, and
sidewalls of at least one protrusion and/or at least one recess of the second die edge, and
wherein the edge interconnect of the at least one protrusion of the first die is in contact with the edge interconnect of the at least one recess of the second die, and/or the edge interconnect of the at least one protrusion of the second die is in contact with the edge interconnect of the at least one recess of the first die such that the first and second dies are electrically coupled to each other through the contacting edge interconnects.

2. The multi-die module of claim 1, wherein the protrusions and the recesses of the first and second die edges are hexagonal, triangular, or rectangular.

3. The multi-die module of claim 1, wherein the first and second dies are dies of different technologies.

4. The multi-die module of claim 3,
wherein the technology of the first die is one of Si, GaAs, POG, AlN, InP, and lumped passive components, and
wherein the technology of the second die is different one of Si, GaAs, POG, InP, and lumped passive components.

5. The multi-die module of claim 1,
wherein the first die includes a plurality of first die edges in which two of the first die edges are shaped the same, and/or
wherein the second die includes a plurality of second die edges in which two of the second die edges are shaped the same.

6. The multi-die module of claim 5,
wherein the protrusions and the recesses of the two first die edges are hexagonal, and/or
wherein the protrusions and the recesses of the two second die edges are hexagonal.

7. The multi-die module of claim 1,
wherein the first die includes a plurality of first die edges in which two of the first die edges are shaped differently, and/or
wherein the second die includes a plurality of second die edges in which two of the second die edges are shaped differently.

8. The multi-die module of claim 7,
wherein one of the two first die edges is straight and the other of the two first die edges includes the protrusions and the recesses, and/or
wherein one of the two second die edges is straight and the other of the two second die edges includes the protrusions and the recesses.

9. The multi-die module of claim 8,
wherein the protrusions and the recesses of the other of the two first die edges are hexagonal, and/or
wherein the protrusions and the recesses of the other of the two second die edges are hexagonal.

10. The multi-die module of claim 1, further comprising a joint paste on the first and second dies overlapping the first and second die edges.

11. A method of fabricating a multi-die module, the method comprising:
forming a first die;
forming a second die; and
assembling the first and second dies such that a first die edge of the first die is in contact with a second die edge of the second die,
wherein the first die edge comprises one or more protrusions and one or more recesses and the second die edge comprises one or more protrusions and one or more recesses such that the protrusions of the first die edge are in contact with recesses of the second die edge and vice versa,
wherein edge interconnects are formed on:
sidewalls of at least one protrusion and/or at least one recess of the first die edge, and
sidewalls of at least one protrusion and/or at least one recess of the second die edge, and
wherein the edge interconnect of the at least one protrusion of the first die is in contact with the edge interconnect of the at least one recess of the second die, and/or the edge interconnect of the at least one protrusion of the second die is in contact with the edge interconnect of the at least one recess of the first die such that the first and second dies are electrically coupled to each other through the contacting edge interconnects.

12. The method of claim 11, wherein the first and second dies are dies formed of different technologies.

13. The method of claim 12,
wherein the technology of the first die is one of Si, GaAs, POG, AlN, InP, and lumped passive components, and
wherein the technology of the second die is different one of Si, GaAs, POG, InP, and lumped passive components.

14. The method of claim 11, wherein forming each of the first die and the second die comprises:
fabricating a wafer of a plurality of dies of a same technology on a wafer substrate, the plurality of dies being formed on a corresponding plurality of die areas of the wafer substrate, each die comprising a first passivation on the wafer substrate, a final metal on the wafer substrate and on the first passivation, and a final passivation on the final metal such that at least a portion of the final metal is exposed through a final via of the final passivation;
forming a trench in in the wafer substrate in between two adjacent dies corresponding to the protrusions and the recesses of the dies;
forming the edge interconnects by metallizing the sidewalls of the trench corresponding to the protrusions and/or the recesses of the dies; and
singulating the plurality of dies into a plurality of individual dies subsequent to forming the edge interconnects,
wherein assembling the first and second dies comprises press fitting the first die and the second die.

15. The method of claim 14, wherein forming each of the first die and the second die further comprises:
forming an under bump metallization (UBM) on the final passivation, the UBM filling the final via so as to be in contact with the final metal, and
forming (840) a bump on the UBM prior to singulating the plurality of dies into the plurality of individual dies.

16. The method of claim 15, wherein the edge interconnects and the UBM are formed simultaneously through a same metallization process.

17. The method of claim 14, wherein the trench is formed such that for at least one die, the protrusions and the recesses of the at least one die have hexagonal, triangular, or rectangular shapes.

18. The method of claim 14, wherein the trench is formed such that for at least one die, two edges of the at least one die are shaped the same.

19. The method of claim 14, wherein the trench is formed such that for at least one die, two edges of the at least one die are shaped differently.

20. The method of claim 19, wherein the trench is formed such that the one of the two edges of the at least one die is straight and the other of the two edges includes the protrusions and the recesses.

21. A multi-die module, comprising:
a laminate; and
a plurality of dies on the laminate, the plurality of dies comprising first and second dies such that a first die edge of the first die is in contact with a second die edge of the second die,
wherein the first die edge comprises one or more protrusions and one or more recesses and the second die edge comprises one or more protrusions and one or more recesses such that the protrusions of the first die edge are in contact with recesses of the second die edge and vice versa,
wherein edge interconnects are formed on:
sidewalls of at least one protrusion and/or at least one recess of the first die edge, and
sidewalls of at least one protrusion and/or at least one recess of the second die edge, and
wherein the edge interconnect of the at least one protrusion of the first die is in contact with the edge interconnect of the at least one recess of the second die, and/or the edge interconnect of the at least one protrusion of the second die is in contact with the edge interconnect of the at least one recess of the first die such that the first and second dies are electrically coupled to each other through the contacting edge interconnects.

22. The multi-die module of claim 21, wherein the protrusions and the recesses of the first and second die edges are hexagonal, triangular, or rectangular.

23. The multi-die module of claim 21, wherein the first and second dies are dies of different technologies.

24. The multi-die module of claim 23,
wherein the technology of the first die is one of Si, GaAs, POG, AlN, InP, and lumped passive components, and
wherein the technology of the second die is different one of Si, GaAs, POG, InP, and lumped passive components.

25. The multi-die module of claim 21,
wherein the first die includes a plurality of first die edges in which two of the first die edges are shaped the same, and/or
wherein the second die includes a plurality of second die edges in which two of the second die edges are shaped the same.

26. The multi-die module of claim 25,
wherein the protrusions and the recesses of the two first die edges are hexagonal, and/or
wherein the protrusions and the recesses of the two second die edges are hexagonal.

27. The multi-die module of claim 21,
wherein the first die includes a plurality of first die edges in which two of the first die edges are shaped differently, and/or
wherein the second die includes a plurality of second die edges in which two of the second die edges are shaped differently.

28. The multi-die module of claim 27,
wherein one of the two first die edges is straight and the other of the two first die edges includes the protrusions and the recesses, and/or
wherein one of the two second die edges is straight and the other of the two second die edges includes the protrusions and the recesses.

29. The multi-die module of claim 28,
wherein the protrusions and the recesses of the other of the two first die edges are hexagonal, and/or
wherein the protrusions and the recesses of the other of the two second die edges are hexagonal.

30. The multi-die module of claim 21, further comprising a joint paste on the first and second dies overlapping the first and second die edges.
